(19) United States
(12) Patent Application Publication
(10) Pub. No.: US 2007/0158687 A1
(43) Pub. Date: Jul. 12, 2007

(54) Base substrate, method of separating the base substrate and plasma display panel using the same

(76) Inventor: Tae-Joung Kweon, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/645,681

(22) Filed: Dec. 27, 2006

(30) Foreign Application Priority Data
Dec. 30, 2005 (KR) 10-2005-0135857

(51) Int. Cl. H01L 31/00

(52) U.S. Cl. 257/198

(57) ABSTRACT

A plasma display panel (PDP) may include a first substrate having first discharge electrodes and a first separation border where the first substrate was separated from a first base substrate and a second substrate having second discharge electrodes and a second separation border where the second substrate was separated from a second base substrate.

### BACKGROUND OF THE INVENTION

1. Field of the Invention

The present invention relates to a method of fabricating a plasma display panel. More particularly, the present invention relates to a base substrate that is separated into a plurality of individual substrates, a method of separating the base substrate into the plurality of individual substrates, a plasma display panel employing individual substrates and a method of manufacturing the plasma display panel.

2. Description of the Related Art

Plasma display panels (PDPs) may be manufactured by fabricating a panel assembly using a first substrate and a second substrate, combining a chassis base with the panel assembly, and installing a driving circuit unit on the chassis base. The resultant structure may be tested to determine acceptability thereof, and an acceptable structure may then be installed in a case.

In order to mass produce PDPs, one base substrate may be prepared, patterns may be formed on the base substrate, and then the base substrate may be separated into a plurality of individual substrates, e.g., a first substrate, a second substrate, . . . , an (n−1)^{th} substrate, and an n^{th} substrate.

Various pattern layers may be formed on an upper surface of the base substrate. For example, a plurality of sustain discharge electrode pairs and a first dielectric layer that buries the sustain discharge electrodes may be formed on a first base substrate, and address electrodes, a rear dielectric layer that covers the address electrodes, barrier ribs and a phosphor layer may be formed on a second base substrate.

Each base substrate may undergo a firing process during formation of the patterns. After the firing process is completed, the base substrate may be separated into the plurality of individual substrates, e.g., by separating along borders of the individual substrates using a cutter.

As a base substrate becomes larger, however, it may become more difficult to achieve uniform quality across the base substrate. This lack of uniformity may be the result of numerous fluctuations, e.g., stress concentration, pattern variation and/or mask variation. These fluctuations may arise from thick film processes, e.g., by a firing process, which may cause thermal stresses, or by a printing process using a mask, e.g., a screen mask, which may cause mechanical stresses.

### SUMMARY OF THE INVENTION

The present invention is therefore directed to a method of separating a base substrate into a plurality of individual substrates and panels made thereby, which substantially overcome one or more of the problems due to the limitations and disadvantages of the related art.

It is therefore a feature of an embodiment of the present invention to provide a base substrate for preventing quality deterioration of panels owing to pattern variation, mask variation or stress concentration during processing a plurality of individual substrates that are successively disposed on the base substrate, a method of separating the base substrate into the plurality of individual substrates, a plasma display panel using the individual substrates and a method of manufacturing the plasma display panel.

At least one of the above features and advantages may be realized by providing a plasma display panel (PDP), including a first substrate including first discharge electrodes and a first separation border where the first substrate was separated from a first base substrate, and a second substrate including second discharge electrodes and a second separation border where the second substrate was separated from a second base substrate.

The first and second separation borders may be oriented in a same direction. The first discharge electrodes may be parallel to the first separation border. The second discharge electrodes may be orthogonal to the second separation border. At least one of the first and second base substrates may satisfy the following relationship: 1.5≦L₁/L₂≦2, where L₁ is a length of a long side of the base substrate and L₂ is a length of a short side of the base substrate.

At least one of the above features and advantages may be realized by providing a method of fabricating a PDP including forming address electrodes on a first base substrate, separating the first base substrate into a plurality of individual first substrates in a direction orthogonal to a direction in which the address electrodes extend, each of the individual first substrates including multiple address electrodes, forming sustain discharge electrode pairs on a second base substrate, separating the second base substrate into a plurality of individual second substrates in a direction parallel to a direction in which the sustain discharge electrode pairs extend, each of the individual second substrates including multiple sustain discharge electrode pairs, and securing at least one of the plurality of individual first substrates and a corresponding one of the plurality of individual second substrate to form at least one PDP.

Forming the address electrodes may include patterning the address electrodes on each of the plurality of individual first substrates to extend along a direction parallel to a long side of the first base substrate.

Separating the first base substrate includes cutting along a respective border between adjacent individual first substrates.

Forming the sustain discharge electrode pairs may include patterning in the sustain discharge electrode pairs in each of the plurality of individual second substrates to extend in a direction parallel to a short side of the second base substrate.

Separating the second base substrate may include cutting along a respective border between adjacent individual second substrates. Securing may include aligning a border along which first individual substrates have been separated from the first base substrate with a border along which the second individual substrates have been separated from second base substrate parallel to each other.

At least one of the above features and advantages may be realized by providing a method of separating a base substrate, including forming discharge electrodes on a base substrate, and separating the base substrate into a plurality of individual substrates along a direction orthogonal to a direction in which the discharge electrodes extend, each of the individual substrates including multiple discharge electrodes.

Forming discharge electrodes may include patterning the discharge electrodes on the base substrate so as to extend in a direction parallel to a long side of the base substrate.

Separating the base substrate includes cutting along respective borders between adjacent individual substrates.

At least one of the above features and advantages may be realized by providing a base substrate which is separated into a plurality of individual substrates each having multiple discharge electrodes, wherein the base substrate satisfies the following relationship: 1.5≦L₁/L₂≦2.0, where L₁ is a length of a long side of the base substrate and L₂ is a length of the short side of the base substrate.

The base substrate may be sequentially partitioned along a direction orthogonal to the long side of the base substrate into a plurality of individual substrates. The discharge electrodes may be address electrodes.

At least one of the above features and advantages may be realized by providing a method of separating a base substrate, including forming discharge electrodes on a base substrate, and separating the base substrate into a plurality of individual substrates along a direction parallel to a direction in which the discharge electrodes extend, each of the individual substrates including multiple discharge electrodes.

Forming discharge electrode may include patterning the discharge electrodes on the base substrate so as to extend in a direction parallel to a short side of the base substrate. Separating the base substrate may include cutting along respective borders between adjacent individual substrates.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates an exploded partial perspective view of a plasma display panel (PDP) according to an embodiment of the present invention;

FIG. 2 illustrates a cross-sectional view of the PDP of in FIG. 1;

FIG. 3 illustrates a plan view of a layout of discharge electrodes of the PDP shown in FIG. 1 according to an embodiment of the present invention;

FIG. 4 illustrates a plan view of a base substrate according to a first embodiment of the present invention;

FIG. 5 illustrates a plan view of a base substrate according to a second embodiment of the present invention; and

FIG. 6 illustrates a plan view of base substrates of FIGS. 4 and 5 that have been separated and combined.

### DETAILED DESCRIPTION OF THE INVENTION

Korean Patent Application No. 10-2005-0135857, filed on Dec. 30, 2005, in the Korean Intellectual Property Office, and entitled: “Base Substrate, Method of Separating Base Substrate and Plasma Display Panel Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, or one or more intervening layers may also be present. In addition, it will also be understood that when a layer is referred to as being “between” two layers, it can be the only layer between the two layers, or one or more intervening layers may also be present. Like reference numerals refer to like elements throughout.

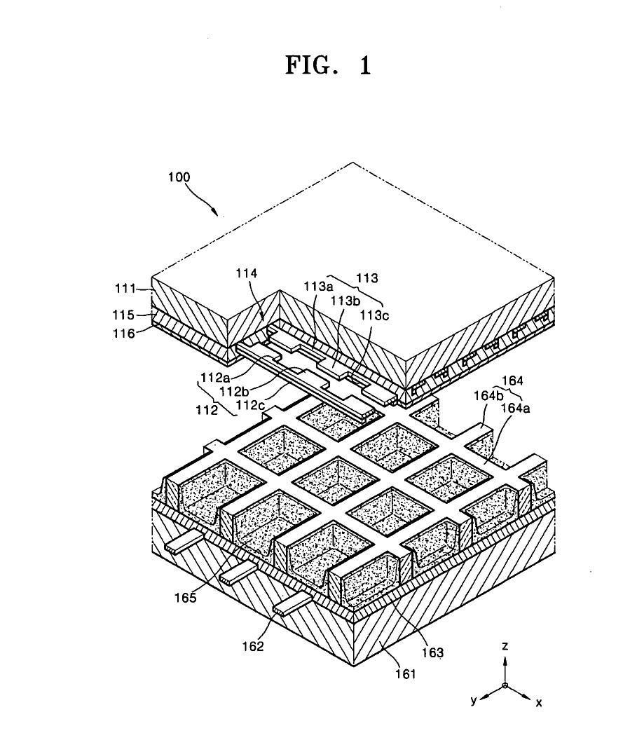

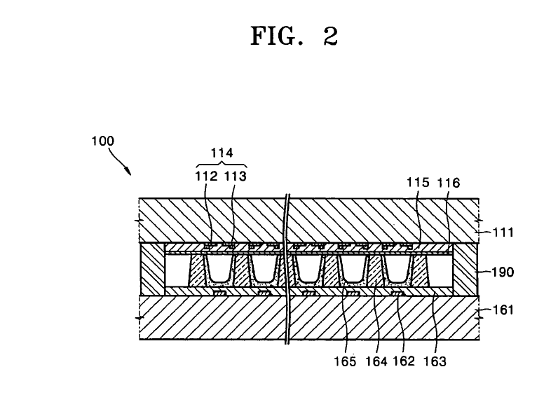

FIG. 1 illustrates an exploded perspective view of a plasma display panel (PDP) 100 according to an embodiment of the present invention, and FIG. 2 illustrates a cross-sectional view of the PDP 100 shown in FIG. 1.

Referring FIGS. 1 and 2, the PDP 100 may include a first substrate 111 and a second substrate 161, which may face the first substrate 111 and be parallel to the first substrate 111. A sealant 190, e.g., frit glass, may be provided on inner side edges of the first substrate 111 and the second substrate 161 to form a sealed inner space. The first substrate 111 and the second substrate 161 are not limited to a particular material, and may be transparent, e.g., soda lime glass, semitransparent, colored, or opaque.

Pairs of sustain discharge electrodes 114 for generating sustain discharge may be disposed parallel to the x direction on an inner surface of the first substrate 111. Pairs of sustain discharge electrodes 114 may include X electrodes 112 and Y electrodes 113. The X electrodes 112 and the Y electrodes 113 may be disposed in an alternating manner in the y direction of the panel 100. At least portions of one pair of the X electrode 112 and the Y electrode 113 may be disposed within one discharge cell.

The X electrodes 112 may each include a first discharge electrode line 112a, which may be a strip, first projecting parts 112b, which may protrude from one side wall of the first discharge electrode line 112a into respective discharge cells, and a first bus electrode line 112c, which may overlap the first discharge electrode line 112a. The Y electrodes 113 may each include a second discharge electrode line 113a, which may be a strip, second projecting parts 113b, which may protrude from one side wall of the second discharge electrode line 113a into the respective discharge cells, and a second bus electrode line 113c, which may overlap the second discharge electrode line 113a. The first projecting parts 112b and the second projecting parts 113b may be disposed a predetermined distance apart from a center of the respective discharge cells.

The first discharge electrode line 112a, the first projecting parts 112b, the second discharge electrode line 113a, and the second projecting parts 113b may be formed using a transparent conductive layer, e.g., an indium tin oxide (ITO ) film, and the first bus electrode line 112c and the second bus electrode line 113c may be made of highly conductive material, e.g., a silver (Ag) paste or other metal materials, such as chrome-copper-chrome, but the materials are not limited thereto.

The X electrodes 112 and the Y electrodes 113 may be under a first dielectric layer 115. The first dielectric layer 115 may be made by adding various fillers to a glass paste. The first dielectric layer 115 may selectively cover only a portion that is patterned as the X electrode 112 and the Y electrode 113, or may be formed with a predetermined thickness on an entire lower surface of the first substrate 111. A protective layer 116, e.g., MgO, may be formed on the surface of the first dielectric layer 115 to prevent damage to the first dielectric layer 115 and increase emission of secondary electrons.

Address electrodes 162 may be disposed on an inner surface of the second substrate 161. The address electrodes 162 may cross the sustain discharge electrode pairs 114, and may be a strip intersecting the discharge cells, which are adjacently disposed in the y direction of the panel 100. The address electrodes 162 may be covered with a second dielectric layer 163.

Barrier ribs 164, which, together with the first and second substrates 111 and 161, may define the discharge cells, may be provided between the first substrate 111 and the second substrate 161. As shown in FIG. 1, the barrier ribs 164 may include first barrier ribs 164a, disposed in the x direction of the panel 100, and second barrier ribs 164b, disposed in the y direction of the panel 100. The first barrier ribs 164a may extend integrally in a direction crossing inner side walls of a pair of the adjacent second barrier ribs 164b. As shown in FIG. 1, the first barrier ribs 164a and the second barrier ribs 164b may form a matrix.

Alternatively, the barrier ribs 164 may form various patterns, e.g., a stripe pattern, a meander pattern, a delta pattern, and a honeycomb pattern.

Further, the discharge cells partitioned by the barrier ribs 164 are not limited to a particular shape, and may be, e.g., rectangular, polygonal, oval, or circular.

The discharge cells defined by the first substrate 111, the second substrate 161 and the barrier ribs 164 may be filled with a discharge gas, e.g., Ne—Xe, or He—Xe.

The inside of the discharge cells may be coated with red, green and blue phosphor layers 165 that, when excited by ultraviolet rays emitted from the discharge gas, emit visible light. The red, green and blue phosphor layers 165 may be coated on inner sides of the barrier ribs 164 in the current embodiment, but may be coated on any area of the barrier ribs 164.

The phosphor layers 165 may be independently coated on each discharge cell. Red phosphor layers may include (Y,Gd)BO₃;Eu⁺³, green phosphor layers may include Zn₂SiO₄:Mn²⁺, and blue phosphor layers may include BaMgAl₁₀O₁₇:Eu²⁺.

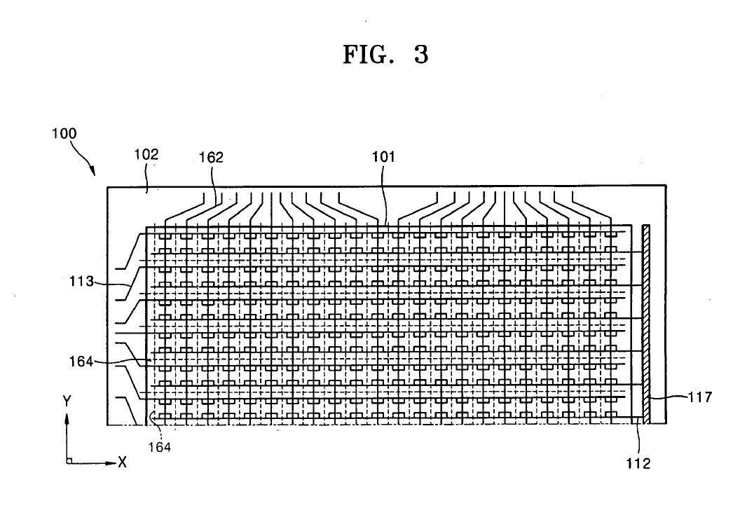

FIG. 3 illustrates an exemplary layout of discharge electrodes of the PDP shown in FIG. 1.

Referring to FIG. 3, the PDP 100 may be divided into a display area 101, which displays images when driven, and a non-display area 102. The non-display area 102 may be in a periphery of the display area 101. The X electrodes 112, the Y electrodes 113 and the address electrodes 162 may be electrically connected to external terminals in the non-display area 102.

The X electrodes 112 may extend across the discharge cells contiguously arranged in the x direction of the panel 100, from the display area 101 to the non-display area 102. Ends of the X electrodes 112 may extend into a first region of the non-display area 102, and may be electrically connected to a common connection electrode line 117, which may extend in the y direction of the panel 100. Therefore, identical voltages may be applied to the X electrodes 112.

The Y electrodes 113 may also extend across the discharge cells contiguously arranged in the x direction of the panel 100, from the display area 101 to the non-display area 102. Ends of the Y electrodes 113 may extend into a second region of the non-display area 102, which may be opposite the first region. The Y electrodes 113 may not be connected with one another or a common line. Thus, different voltages may be applied to the Y electrodes 113.

The address electrodes 162 may be disposed to cross the discharge cells contiguously arranged in the y direction of the panel 100, from the display area 101 to the non-display area 102. The address electrodes 162 may be disposed over the entire area of the panel 100, and may extend across the X electrodes 112 and the Y electrodes 113. Ends of each address electrode 162 may extend into a third region of the non-display area 102, different from the first and second regions, and may not be connected with one another.

Thus, the discharge sustain electrodes 114, i.e., the pair of X and Y electrodes 112 and 113, and the address electrodes 162 may be individually arranged in different directions from each other on the panel 100, and may be electrically connected to external terminals, e.g., a flexible printed cable, in the non-display area 102 of the panel 100.

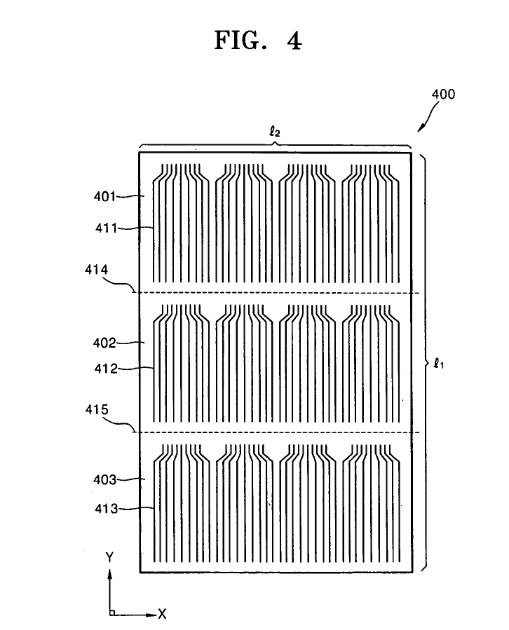

FIG. 4 illustrates a first base substrate 400 according to a first embodiment of the present invention.

Referring to FIG. 4, the first base substrate 400 may be a mother substrate, which may be separated into a plurality of substrates, e.g., a first substrate, a second substrate, . . . , an (n−1)^{th} substrate, and an nth substrate.

In the particular configuration shown in FIG. 4, the first base substrate 400 may be separated into three substrates, i.e., a first substrate 401, a second substrate 402, and a third substrate 403.

The first substrate 401, the second substrate 402, and the third substrate 403 may be defined sequentially in the y direction of the first base substrate 400. First address electrodes 411 may be patterned on the first substrate 401; second address electrodes 412 may be patterned on the second substrate 402; third address electrodes 413 may be patterned on the third substrate 403.

The first, second and third address electrodes 411, 412 and 413 may be of substantially the same size and shape, and, according to the current embodiment, may each be a strip. The first, second and third address electrodes 411, 412 and 413 may be disposed parallel to the y direction of the first base substrate 400. Multiple ends of the first, second, and third address electrodes may be grouped at edges of the first, second, and third substrates 401, 402 and 403, but may remain electrically independent of one another.

The first, second, and third substrate 401, 402 and 403 may be separated, e.g., cut by a cutter (not shown), at a first border 414 between the first substrate 401 and the second substrate 402, and at a second border 415 between the second substrate 402 and the third substrate 403. The first border 414 and the second border 415 may be orthogonal to the direction in which the first, second, and third address electrodes 411, 412 and 413 extend, e.g., may extend along the x direction of the first base substrate 400.

A length of a long side (l₁) and a length of a short side (l₂) of the first base substrate 400 may satisfy Equation 1 below:

1.5≦l₁/l₂≦2.0 <Equation 1>

When l₁/l₂ is smaller than 1.5, material may be wasted, since the first, second and third substrates 401, 402 and 403 may not be realized from the first base substrate 400. When l₁/l₂ is larger than 2.0, the first base substrate 400 may be separated into the first, second and third substrates 401, 402 and 403 or more. However, as the length of the long side l₂ of the first base substrate 400 increases, thermal variation may occur during firing.

Thus, the first base substrate 400 may be separated along at least two borders in the direction orthogonal to the direction along which the first, second and third address electrodes 411, 412 and 413 extend.

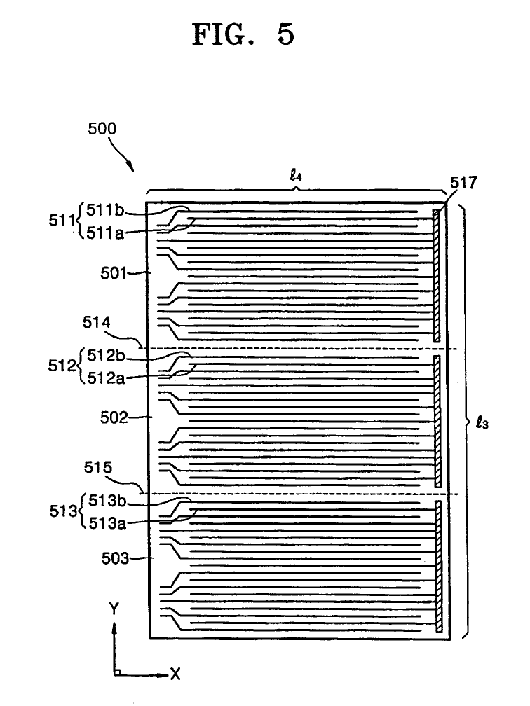

FIG. 5 illustrates a second base substrate 500 according to a second embodiment of the present invention.

Referring to FIG. 5, the second base substrate 500 may be a mother substrate that may be separated into a plurality of substrates, e.g., a first substrate, a second substrate, . . . , an (n−1)^{th} substrate, and an n^{th} substrate.

Each individual substrate of the second base substrate 500 may be combined with each individual substrate of the first base substrate 400 of the first embodiment to fabricate a PDP.

The second base substrate 500 may be partitioned into a fourth substrate 501, a fifth substrate 502, and a sixth substrate 503 in the y direction of the second base substrate 500. First sustain discharge electrodes 511 may be disposed on the fourth substrate 501; second sustain discharge electrodes 512 may be disposed on the fifth substrate 502; third sustain discharge electrodes 513 may be disposed on the sixth substrate 503.

The first, second and third sustain discharge electrode pairs 511, 512 and 513 may include X electrodes 511a, 512a and 513a, and Y electrodes 511b, 512b and 513b correspondingly, and may be of substantially the same size and shape.

The X electrodes 511a, 512a and 513a may each independently extend to a first side of the second base substrate 500, and may be electrically connected to a respective connection electrode line 517 of the fourth, fifth, and sixth substrates 501, 502 and 503. The Y electrodes 511b, 512b and 513b may extend to a second side, which may be opposite the first side. Unlike the X electrodes 511a, 512a and 513a, the Y electrodes 511b, 512b and 513b may not be electrically connected to one another. Multiple ends of the Y electrodes 511b, 512b and 513b may be grouped, but may remain electrically independent of one another.

The fourth, fifth and sixth substrate 501, 502, 503 may be separated, e.g., cut by a cutter, at a third border 514 between the fourth substrate 501 and the fifth substrate 502, and at a fourth border 515 between the fifth substrate 502 and the sixth substrate 503. The third border 514 and the fourth border 515 may be parallel to the direction where the first, second, and third sustain discharge electrodes pairs 511, 512 and 513 extend, e.g., may extend along the x direction of the second base substrate 500.

A length of a long side (l₃) and a length of a short side (l₄) of the second base substrate 500 may satisfy the following Equation 2:

1.5≦l₃/l₄≦2.0 <Equation 2>

When l₃/l₄ is smaller than 1.5, material may be wasted, since the fourth through sixth substrates 501 through 503 may not be realized from the second base substrate 500. When l₃/l₄ is larger than 2.0, the base substrate may be separated into the fourth through sixth substrates 501 through 503 or more. However, as the length of the long side l₃ of the second base substrate 500 increases, thermal variation may occur during firing.

Thus, the second base substrate 500 may be separated along at least two borders in the direction parallel to the direction in which the first, second and third sustain discharge electrodes pairs 511, 512, 513 extend.

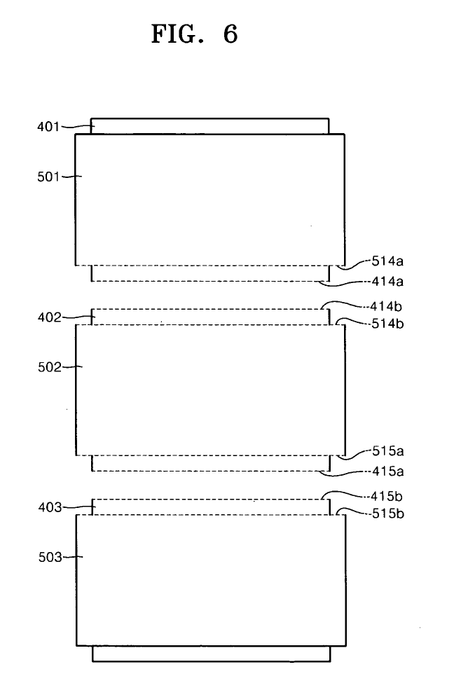

FIG. 6 illustrates a combined state of a plurality of individual substrates from the first base substrate 400 of FIG. 4 and the second base substrate 500 of FIG. 5.

Referring to FIG. 6, the first base substrate 400 may be separated into the first substrate 401, the second substrate 402 and the third substrate 403, and the second base substrate 500 may be separated into the fourth substrate 501, the fifth substrate 502 and the sixth substrate 503.

The first substrate 401 and the fourth substrate 501 may be combined to form a first PDP; the second substrate 402 and the fifth substrate 502 may be combined to form a second PDP; the third substrate 403 and the sixth substrate 503 may be combined to form a third PDP.

A lower border 414a of the first substrate 401 and a lower border 514a of the fourth substrate 501, an upper border 414b of the second substrate 402 and a upper border 514b of the fifth substrate 502, a lower border 415a of the second substrate 402 and a lower border 515a of the fifth substrate 502, and an upper border 415b of the third substrate 403 and an upper border 515b of the sixth substrate 503 may be oriented in the same direction.

A method of fabricating a plurality of PDPs using a base substrate will be described below, referring to FIGS. 4 through 6.

First, the first base substrate 400 may be prepared. Then, the first address electrodes 411, the second address electrodes 412 and the third address electrodes 413 may be patterned onto corresponding areas of the first substrate 401, the second substrate 402 and the third substrate 403.

The first, second and third address electrodes 411, 412 and 413 may be patterned along the long side of the first base substrate 400, i.e., parallel to the y direction, and may be substantially of the same shape and size.

After the first, second and third address electrodes 411, 412 and 413 have been patterned, a firing process may be performed at a predetermined temperature. Then, a second dielectric layer (not shown), which may bury the first, second and third address electrodes 411, 412 and 413, may be printed and fired. Then, when the PDP is a three-electrode surface discharge type PDP, barrier ribs (not shown), for defining discharge cells, may be formed on the upper surface of the second dielectric layer and fired.

Next, the first base substrate 400 may be separated along the first border 414 between the first substrate 401 and the second substrate 402, and the second border 415 between the second substrate 402 and the third substrate 403. The borders may be orthogonal to the direction in which the first, second and third address electrodes 411, 412 and 413 extend.

The second base substrate 500 may be prepared. A plurality of sustain discharge electrode pairs 511, 512 and 513 may be patterned onto corresponding areas of the fourth substrate 501, the fifth substrate 502 and the sixth substrate 503.

The first, second and third sustain discharge electrode pairs 511, 512 and 513 may be patterned into the X electrodes 511a, 512a and 513a and the Y electrodes 511b, 512b and 513b, which may be alternately disposed with respect to the X electrodes 511a, 512a and 513a. Ends of the X electrodes 511a, 512a and 513a may be electrically connected to one another, e.g., through the connecting electrode line 517, in the first region of the second base substrate 500. The first, second and third sustain discharge electrode pairs 511, 512 and 513 may be disposed parallel to the short side, i.e., the x direction, of the second base substrate 500, and may be of the same shape and size.

The first, second and third sustain discharge electrode pairs 511, 512 and 513 may be formed by overlapping a transparent conductive layer, e.g., an ITO film, and a highly conductive metal material for reducing line resistance of the electrodes, e.g., an Ag paste, or may be formed using only metal materials, i.e., various embodiments may be employed.

After the first, second and third sustain discharge electrode pairs 511, 512 and 513 are patterned and fired at a predetermined temperature, a first dielectric layer (not shown), which may bury the first, second and third sustain discharge electrode pairs 511, 512 and 513, may be formed. When the PDP is a three-electrode surface discharge type PDP, a protecting layer (not shown), e.g., an MgO layer, may be formed on the surface of the first dielectric layer.

Then, the second base substrate 500 may be separated along the third border 514 between the fourth substrate 501 and the fifth substrate 502, and the fourth border 515 between the fifth substrate 502 and the sixth substrate 503. The borders may be parallel to the direction where the first, second and third sustain discharge electrode pairs 511, 512 and 513 extend.

Next, the first, the second and the third substrates 401, 402, 403 may be combined with the fourth, the fifth and the sixth substrates 501, 502, 503, respectively, to form three PDPs.

When the individual substrates from the first base substrate 400 and the second base substrate 500 are combined, the borders of the first, second and third substrates 401, 402 and 403, and the borders of the fourth, fifth and sixth substrates 501, 502 and 503 may be oriented in the same direction.

Therefore, the first substrate 401 and the fourth substrate 501 may be combined in a state where the lower border 414a of the first substrate 401 and the lower border 514a of the fourth substrate 501 are respectively oriented in the same direction. Likewise, the second substrate 402 and the fifth substrate 502 may be combined in a state where the upper and lower borders 414b and 415a of the second substrate 402 and the upper and lower borders 514b and 515a of the fifth substrate 502 are respectively oriented in the same directions. Also, the third substrate 403 and the sixth substrate 503 may be combined in a state where the upper border 415b of the third substrate 403 and the upper border 515b of the sixth substrate 503 are respectively oriented in the same direction.

While the embodiment shown in FIG. 6 illustrates then first through third substrates 401 through 403 being respectively combined with the fourth through sixth substrates 501 through 503, this combination may be rearranged, as long as the borders are parallel to one another. In other words, the first substrate 401 may be combined with any of the fourth through sixth substrates 501 through 503, etc. For example, the first substrate 401 can be combined with the fifth substrate 502; the second substrate 402 can be combined with the sixth substrate 503; the third substrate 403 can be combined with the fourth substrate 501. Thus, combination of substrates is not particularly limited thereto, as long as the borders where individual substrates have been separated from the first base substrate 400 and the second base substrate 500 are parallel.

Then, a sealant (not shown), e.g., a frit glass, may be provided along inner side edges of the combinations of the first through third substrates 401 through 403 and the fourth through sixth substrates 501 through 503, and respective PDPs formed thereby may be sealed.

The base substrate, method of separating the base substrate and plasma display panel using the base substrate according to the present invention may provide various effects described below.

First, separating the base substrate that is patterned with the address electrodes in the direction orthogonal to the address electrodes may reduce pattern variation that may arise by thermal variation during firing.

Second, more uniform address electrodes may simplify alignment with the barrier ribs or phosphor layers that are formed later.

Third, when forming the address electrodes using a mask, a width of the mask may be reduced by aligning the address electrodes parallel to the long side of the base substrate, so that variation of the address electrode pattern due to unequal tension on the mask may be reduced or prevented.

Fourth, stable yield may be achieved by various combinations of the first base substrate on which the address electrodes are arranged and the second base substrate on which the sustain discharge electrode pairs are arranged through aligning the borders to be parallel.

Exemplary embodiments of the present invention have been disclosed herein, and although specific terms are employed, they are used and are to be interpreted in a generic and descriptive sense only, and not for purpose of limitation. Accordingly, it will be understood by those of ordinary skill in the art that various changes in form and details may be made without departing from the spirit and scope of the present invention as set forth in the following claims.

What is claimed is:

1. A plasma display panel (PDP), comprising:
a first substrate including first discharge electrodes and a first separation border where the first substrate was separated from a first base substrate; and
a second substrate including second discharge electrodes and a second separation border where the second substrate was separated from a second base substrate.

2. The PDP as claimed in claim 1, wherein the first and second separation borders are oriented in a same direction.

3. The PDP as claimed in claim 2, wherein the first discharge electrodes are parallel to the first separation border.

4. The PDP as claimed in claim 2, wherein the second discharge electrodes are orthogonal to the second separation border.

5. The PDP as claimed in claim 2, wherein at least one of the first and second base substrates satisfies the following relationship:
1.5≦L₁/L₂≦2.0
where L₁ is a length of a long side of the base substrate and L₂ is a length of a short side of the base substrate.

6. A method of fabricating a plasma display panel (PDP), comprising:
forming address electrodes on a first base substrate;
separating the first base substrate into a plurality of individual first substrates in a direction orthogonal to a direction in which the address electrodes extend, each of the individual first substrates including multiple address electrodes;
forming sustain discharge electrode pairs on a second base substrate;
separating the second base substrate into a plurality of individual second substrates in a direction parallel to a direction in which the sustain discharge electrode pairs extend, each of the individual second substrates including multiple sustain discharge electrode pairs; and
securing at least one of the plurality of individual first substrates and a corresponding one of the plurality of individual second substrate to form at least one PDP.

7. The method as claimed in claim 6, wherein forming the address electrodes includes patterning the address electrodes on each of the plurality of individual first substrates to extend along a direction parallel to a long side of the first base substrate.

8. The method as claimed in claim 6, wherein separating the first base substrate includes cutting along a respective border between adjacent individual first substrates.

9. The method as claimed in claim 6, wherein forming the sustain discharge electrode pairs includes patterning in the sustain discharge electrode pairs in each of the plurality of individual second substrates to extend in a direction parallel to a short side of the second base substrate.

10. The method as claimed in claim 6, wherein separating the second base substrate includes cutting along a respective border between adjacent individual second substrates.

11. The method as claimed in claim 6, wherein securing includes aligning a border along which first individual substrates have been separated from the first base substrate with a border along which the second individual substrates have been separated from second base substrate parallel to each other.

12. A method of separating a base substrate, comprising:
forming discharge electrodes on a base substrate; and
separating the base substrate into a plurality of individual substrates along a direction orthogonal to a direction in which the discharge electrodes extend, each of the individual substrates including multiple discharge electrodes.

13. The method as claimed in claim 12, wherein forming discharge electrodes includes patterning the discharge electrodes on the base substrate so as to extend in a direction parallel to a long side of the base substrate.

14. The method as claimed in claim 12, wherein separating the base substrate includes cutting along respective borders between adjacent individual substrates.

15. A base substrate which is separated into a plurality of individual substrates each having multiple discharge electrodes, wherein the base substrate satisfies the following relationship:
1.5≦L₁/L₂≦2.0
where L₁ is a length of a long side of the base substrate and L₂ is a length of the short side of the base substrate.

16. The base substrate as claimed in claim 15, wherein the base substrate is sequentially partitioned along a direction orthogonal to the long side of the base substrate into a plurality of individual substrates.

17. The base substrate as claimed in claim 12, wherein the discharge electrodes are address electrodes.

18. A method of separating a base substrate, comprising:
forming discharge electrodes on a base substrate; and
separating the base substrate into a plurality of individual substrates along a direction parallel to a direction in which the discharge electrodes extend, each of the individual substrates including multiple discharge electrodes.

19. The method as claimed in claim 18, wherein forming discharge electrode includes patterning the discharge electrodes on the base substrate so as to extend in a direction parallel to a short side of the base substrate.

20. The method as claimed in claim 18, wherein separating the base substrate includes cutting along respective borders between adjacent individual substrates.
